(19) United States
(12) Patent Application Publication
(10) Pub. No.: US 2026/0043854 A1
(43) Pub. Date: Feb. 12, 2026

(54) Method for Monitoring Battery Cells of a Battery of a Motor Vehicle, Computer Program, Data Processing Device and Motor Vehicle

(71) Applicant: Bayerische Motoren Werke Aktiengesellschaft, Muenchen (DE)

(72) Inventor: Jose LOPEZ DE ARROYABE, Muenchen (DE)

(21) Appl. No.: 19/102,629

(22) PCT Filed: Aug. 7, 2023
(86) PCT No.: PCT/EP2023/071837

§ 371 Date: Feb. 10, 2025

(30) Foreign Application Priority Data
Aug. 16, 2022 (DE) 10 2022 120 558.4

(51) Int. Cl. G01R 31/367; B60L 58/16; G01R 31/3842; G01R 31/389; G01R 31/392; G01R 31/396

(52) U.S. Cl. CPC G01R 31/367; B60L 58/16; G01R 31/3842; G01R 31/389; G01R 31/392; G01R 31/396

(57) ABSTRACT

A method for monitoring battery cells of a motor vehicle includes detecting a time series of cell status variables characterizing the battery cells, determining a status vector by inputting the time series into a first neural network, determining an impedance spectrum of the battery cells by impedance spectroscopy, and determining status information for monitoring the battery cells by inputting the impedance spectrum and the status vector into a second neural network.

### BACKGROUND AND SUMMARY

The present disclosure relates to a method for monitoring battery cells of a battery of a motor vehicle, and a data processing device designed to at least partially carry out the method. Furthermore, a motor vehicle having the data processing device is provided. Additionally or alternatively, a computer program is provided that comprises commands which, upon the execution of the program by a computer, prompt it to at least partially carry out the method. Additionally or alternatively, a computer-readable medium is provided that comprises commands which, upon the execution of the commands by a computer, prompt it to at least partially carry out the method.

The disclosure relates to rechargeable batteries or accumulators which can be used, for example, as traction batteries for electrically drivable motor vehicles. Such batteries typically have an interconnection of multiple battery cells. These battery cells are to be monitored during their operation. For this purpose, monitoring a cell voltage and a temperature of the battery cells by voltage sensors and temperature sensors on the battery cells is known, for example. However, it is also desirable to monitor a dynamic behavior of the battery cells which describes, for example, an aging of the battery cells. In the development of battery cells, batteries, and electric vehicles, the state of the battery chemistry is relevant for the operation of the motor vehicle, in particular for calculating a remaining range of the motor vehicle.

In particular in battery cells based on lithium ferrophosphate (LiFePo, LFP), the calculation of the state of charge (SOC) and/or the state of health (SOH) is particularly difficult. SOC and/or SOH are typically determined via a measurement of an open circuit voltage (OCV). In this case, a voltage is measured for each individual battery cell and a state of charge corresponding to the measured voltage is determined in a lookup table comprising a relationship between the voltage and the state of charge. However, the OCV curve is comparatively flat in the case of LFP battery cells, due to which SOC can be determined only with difficulty and/or with low reliability. For example, in an SOC range of 30% to 55%, a voltage difference of approximately 8 mV can result, in an SOC range from 65% to 95%, however, only another voltage difference of approximately 2 mV. Known algorithms for determining the SOC, which were developed for battery cells based on lithium nickel manganese cobalt oxides (NMC), are inaccurate. A comparatively large buffer for reserving energy is therefore necessary for operating the motor vehicle in order to avoid a discharge of the battery and shutdown of the motor vehicle.

In addition to the OCV curve, so-called energy integrators are used, which integrate the current over time, for example, to add up the consumed energy. The SOC can be determined reliably, but in a complex manner thereby. Current integrators which have a lower accuracy, however, are used in the motor vehicle. Current pulse measuring methods are applied in the laboratory and/or on the test bench to determine the SOH.

Electrochemical impedance spectroscopy can be carried out to improve the prediction and calculation of, for example, SOC and/or SOH in the motor vehicle. This measurement method generates additional cell information which displays more sensitivity with respect to cell status indicators such as SOC and SOH.

Monitoring battery cells by impedance spectroscopy is known for this purpose from the prior art. In galvanostatic impedance spectroscopy, a current signal having currents of different frequencies is applied to the battery cells as an excitation signal and the frequency-dependent cell voltage signal of the battery cells is detected as a response signal. The impedance spectrum of the battery cells is determined from the relationship between the current signal and the cell voltage signal.

DE 10 2019 125 014 A1 discloses a method for monitoring battery cells of a battery of a motor vehicle by galvanostatic impedance spectroscopy. In the method, a current signal having currents of different frequencies is applied to the battery cells as an excitation signal. In addition, cell voltage signals of the battery cells are detected as frequency-dependent response signals to the excitation signal and impedance spectra of the battery cells are determined as a function of the excitation signal and the response signals.

However, carrying out impedance spectroscopy is not possible or is possible with less reliability in specific scenarios. For example, it is difficult to carry out an impedance measurement when driving the motor vehicle, because a direct current applied to the battery cells is to remain constant so that the impedance measurement can take place reliably under certain circumstances.

In addition, it is known that the measurable properties of the battery cells, for example, the OCV curve and/or the impedance spectrum, are dependent on the history of the battery cells, thus have a hysteresis. I.e. when a measurement of the voltage or the impedance results in a specific value, various SOC and SOH can have to be assigned to the measurements. The assignment of SOC and SOH is dependent on how the battery cell has arrived at the measurement. The chronological development of current direction and/or the amperage is meaningful here, for example, as described in ROSCHER, Michael A. ; VETTER, Jens; SAUER, Dirk Uwe; Characterisation of charge and discharge behaviour of lithium ion batteries with olivine based cathode active material; Journal of Power sources, 2009, volume 191, issue 2, pages 582-590.

Against the background of this prior art, an object of the present disclosure is to specify an improved method for monitoring battery cells of a battery of a motor vehicle which is suitable for enhancing the prior art. A specific embodiment of the disclosure can achieve the object of enabling more reliable and comprehensive monitoring of the battery cell.

This object is achieved by the features of the present disclosure, which also includes optional aspects and/or refinements of the disclosure as the content.

Accordingly, the object is achieved by a method for monitoring battery cells of a battery of a motor vehicle. The method comprises: detecting a time series of cell state variables characterizing the battery cells; ascertaining a state vector by inputting the time series into a first neural network; determining an impedance spectrum of the battery cells by impedance spectroscopy; and ascertaining state information for monitoring the battery cells by inputting the impedance spectrum and the state vector into a second neural network.

The motor vehicle comprises the battery. The battery comprises a plurality of battery cells to be monitored. The state of each of the batteries can be characterized by the cell state variable. The cell state variable can in particular comprise information which characterizes the current state of the battery cell and/or the current performance of the battery cell. The cell state variable is measurable by a measurement on the battery cell. The time series of the cell state variables can be ascertained by a repeated measurement of the cell state variable, thus a chronological sequence of measured values of the cell state variables. The time series of the cell state variables can give information about a chronological dependence of the cell state variables. For this purpose, the time series can comprise one timestamp per cell state variable which indicates the time of the measurement of the cell state variable. The history or past of the battery cells or of the state of the battery cells can be characterized by the time series. The cell state variables can be measured to ascertain the time series in particular during a journey or during an operation of the motor vehicle.

The time series of the cell state variables is input into the first neural network. The first neural network is configured to ascertain the state vector from the time series of the cell state variables. The state vector is a one-dimensional or multidimensional vector comprising one or more numeric values which indicate the state of the battery cell and the chronological development of the battery cell. The state vector does not have to have information which is readable and/or comprehensible by a user in this case, because the state vector is intended to be input into the second neural network for further processing.

The impedance spectrum of the battery cells is determined by impedance spectroscopy. The impedance spectroscopy is carried out, for example, as disclosed in DE 10 2019 125 014 A1. A current signal having currents of different frequencies is applied as an excitation signal to the battery cells. In addition, cell voltage signals of the battery cells are detected as frequency-dependent response signals to the excitation signal and impedance spectra of the battery cells are determined as a function of the excitation signal and the response signals. The impedance spectra are dependent on the state of the battery cell, thus the state of charge and the state of health, and the history or the past of the battery cell.

The state information is used for monitoring the battery cell and can comprise information readable by a user and/or can result in information readable by a user by further processing. For example, the state information can comprise the state of charge and/or the state of health. In order that the state information is ascertained, the impedance spectrum and the state vector are input into the second neural network. The second neural network is configured to ascertain the state information on the basis of the impedance spectrum and the state vector.

It was recognized here that due to the use of the two neural networks, the problem of the time-dependence of the measurements of the hysteresis can be reliably avoided. In order to overcome the problem of the time dependence of the impedance measurement, it is proposed that the history of the cell chemistry be recorded in a first step by measurement inputs present in the vehicle and processed by the first neural network without having to carry out impedance spectroscopy. To improve an estimation of the cell state by the impedance spectroscopy in the time series, it is proposed that the output of the first neural network, thus the state vector, be combined with the data of the impedance spectroscopy in a vector and this common vector be input into the second neural network in order to calculate the state information.

An improved ascertainment of the state of charge and/or the state of health is therefore possible and, for example, the range reserve can be reduced. A significant battery cost reduction, in particular in the case of LFP batteries, is therefore enabled by a reduction of the range reserve. Furthermore, the remaining range can be increased by a precise cell state estimation, which takes into consideration both the cell history by way of the first neural network and the impedance spectroscopy by way of the second neural network. It is made possible by the method to obtain a time curve of the cell chemistry as important information for the state estimation during a dynamic journey with nonconstant direct current.

The cell state variables can comprise a cell current, a cell voltage, a cell temperature, and/or a variable derived therefrom. The cell current is the current of the battery cell to be monitored. The current is the current usable for an electric drive and can have a different sign when charging the battery cell and/or recuperating than when driving the motor vehicle. The current is distributed through the cells, which are connected in parallel in the storage device. The cell voltage is the voltage of the battery cell to be monitored. The cell temperature is the temperature of the battery cell to be monitored. The current state of the battery cell can be comprehensively characterized by the cell current, the cell voltage, and the cell temperature. A comprehensive characterization of the chronological development of the state of the battery cell is therefore possible on the basis of the time series of the cell state variables. The derived variable can comprise, for example, a gradient of a current, voltage, and/or temperature curve. The derived variable can comprise a time integration of a current, voltage, and/or temperature variable. The derived variable can alternatively or additionally in particular comprise a difference between two current values, two voltage values, and/or two temperature values.

The determination of the impedance spectrum can take place when a chronological development of the cell current and/or the cell voltage meets a predetermined condition. The predetermined condition is definable here such that the impedance measurement is reliably possible. For example, the predetermined condition can relate to a fluctuation, variance, and/or standard deviation of the cell current and/or the cell voltage characterizing the dynamic of the cell current and/or the cell voltage. If the dynamic of the cell current and/or the cell voltage is less than a predetermined threshold value, the impedance measurement can take place. Otherwise, if the dynamic of the cell current and/or the cell voltage is greater than the threshold value, the impedance measurement does not take place and occurs at a later time at which the chronological development of the cell current and/or the cell voltage meets the predetermined condition.

The determination of the impedance spectrum can take place when the cell current is constant i.e. when the dynamic in the chemistry of the battery cell is low. For example, a constant cell current indicates a low chemistry dynamic and means here that the cell current and therefore the cell voltage is sufficiently constant for an impedance measurement by impedance spectroscopy. The chronological development of the cell voltage and/or the cell current is substantially stationary here. For example, it can be sufficient if the cell voltage and/or the cell current only changes by a few percent and/or parts per thousand within a few seconds. If the cell voltage and/or the cell current is constant in this sense, the chronological development of the cell current meets a predetermined condition. On the other hand, if the cell voltage and/or the cell current is not constant in this sense, the impedance measurement does not take place and occurs at a later time at which the cell current is substantially constant and meets the predetermined condition. For the same reasons, the determination of the impedance spectrum can take place when the cell current falls below a predetermined cell current threshold. The cell current threshold can be dependent on the chemistry of the battery cells.

The determination of the impedance spectrum can take place when the cell voltage is constant and/or the chronological development of the cell voltage meets a predetermined fluctuation condition. For example, a constant cell voltage indicates a low chemistry dynamic and means here that the cell voltage is sufficiently constant for an impedance measurement by impedance spectroscopy. The chronological development of the cell voltage is largely stationary. For example, it can be sufficient if the cell voltage only changes by a few percent and/or parts per thousand within several seconds. In particular, it can be sufficient if the cell voltage only changes by a few millivolts within several seconds. If the cell voltage is constant in this sense, the chronological development of the cell voltage meets the predetermined fluctuation condition. Otherwise, if the cell voltage is not constant in this sense, the impedance measurement does not take place and occurs at a later time at which the cell voltage is largely constant and meets the predetermined fluctuation condition. The fluctuation condition can be dependent on the chemistry of the battery cell.

The first neural network can comprise a recurrent neural network (RNN), for example, a long short-term memory network (LSTM). The RNNs are capable of detecting chronological information. It is therefore possible to effectively characterize the time series. The first neural network therefore comprises time feedback which connects measured values at a later time with measured values at an earlier time. The history of the battery cell can therefore be reliably taken into consideration in order to determine the state network.

The second neural network can be a fully connected neural network (DNN) and/or a convolutional neural network (CNN). The second neural network is therefore efficiently trainable and can simultaneously process complex and high-dimensional inputs, as result from the combination of state vector and impedance spectrum.

The second neural network can have a first layer for the input of the impedance spectrum and a second layer downstream of the first layer for the input of the state vector. Therefore, initially efficient processing of the impedance spectrum can take place and then the state vector can be input into the second neural network, for example, in order to reduce a dimension of a variable to be input.

The description above can be summarized as follows in other words and with respect to a specific embodiment, which is described as not limiting for the present disclosure: The disclosure relates to an AI method for cell state identification in the vehicle by electrochemical impedance spectroscopy. The prior art to implement the cell state identification comprises monitoring the OCV curve of the battery cells. In addition, energy integrators are used. These integrate the current over time, for example, to add up the consumed energy, in order to determine the SOC. To determine the SOH, current pulse measuring methods are often applied in the laboratory and/or on the test bench. The prior art is in need of improvement in the following aspects: 1) The OCV curve is not capable of identifying the cell state for all chemistries or battery cell types. In particular with LFP cells, the OCV curve method is not very suitable because of a lack of slope and hysteresis. 2) Energy integrators which integrate the energy over time are very good for the state determination and are used above all on the test bench. They meet high requirements for the voltage and current sampling rate here. They have the disadvantage that they are too costly for use in motor vehicles. 3) The known cell state identification methods rarely take into consideration the electrical history of the chemistry. To avoid these problems, the following method has been proposed, which is constructed using a corresponding sequence of AI structures: 1) To avoid the problem of the impedance measurement during the journey, it is proposed that, in a first step, the history of the cell chemistry be recorded during the journey using an LSTM AI structure based on the measuring inputs present in the vehicle (among other things, current, voltage, temperature), without having to carry out an impedance measurement. 2) In order to significantly improve the cell state estimation by impedance measurement with regard to the history, it is proposed that an impedance measurement be created when the DC current is constant, for example, when the motor vehicle is parked, is stationary at a traffic signal, and/or takes a constant current from the battery. The output of the LSTM AI structure is then combined with the impedance measurement data in a vector. This common vector is input into a second AI structure, for example, a fully connected/dense layer having, for example, a sigmoid output activation function in order to calculate the target cell state parameter, for example, an SOC or SOH.

Furthermore, a computer program is provided comprising commands which, upon the execution of the program by a computer, prompt it to at least partially execute or carry out the above-described method.

A program code of the computer program can be present in any code, in particular in a code which is suitable for controllers of motor vehicles.

The description above with respect to the method also applies analogously to the computer program and vice versa.

Furthermore, a data processing device, such as a control unit, for an automated motor vehicle is provided, wherein the data processing device is configured to at least partially execute or carry out the above-described method. The method is therefore a computer-implemented method.

The data processing device can be part of a driver assistance system or can represent it. The data processing device can be, for example, an electronic control unit (ECU). The electronic control unit can be an intelligent processor-controlled unit which can communicate with other modules, for example, via a central gateway (CGW) and which can optionally form the vehicle onboard network via field buses, such as the CAN bus, LIN bus, MOST bus, and FlexRay or via automotive ethernet, for example, together with telematics control units. It is conceivable that the control unit controls functions relevant for the driving behavior of the motor vehicle, such as the engine control, the force transmission, the braking system, and/or the tire pressure monitoring system. The data processing device can also, for example, be located in a cloud or, for example, can be operated by a vehicle-external server, and can be connected and/or connectable to the motor vehicle by data transmission.

The description above with respect to the method and to the computer program also applies analogously to the data processing device and vice versa.

Furthermore, a motor vehicle comprising the above-described data processing device is provided.

The motor vehicle can be a passenger vehicle, in particular an automobile. The optionally automated motor vehicle can be designed to at least partially and/or at least temporarily take over a longitudinal guidance and/or a lateral guidance during automated driving of the motor vehicle. The automated driving can take place so that the forward movement of the motor vehicle takes place (largely) autonomously. Automated driving can be at least partially and/or temporarily controlled by the data processing device. The motor vehicle can be a motor vehicle of autonomy level 0 to 5.

The description above with respect to the method, the data processing device, and the computer program also applies analogously to the motor vehicle and vice versa.

Furthermore, a computer-readable medium is provided, in particular a computer-readable storage medium. The computer-readable medium comprises commands which, upon the execution of the program by a computer, prompt it to at least partially carry out the above-described method.

I.e., a computer-readable medium can be provided which comprises an above-described computer program. The computer-readable medium can be any digital data memory device, such as a USB stick, a hard drive, an SD card, or an SSD card. The computer program does not necessarily have to be stored on such a computer-readable storage medium in order to be made available to the motor vehicle, but rather it can also be acquired via the Internet or externally in another way.

The description above with respect to the method, the data processing device, the computer program, and the automated motor vehicle also applies analogously to the computer-readable medium and vice versa.

An embodiment is described hereinafter with reference to FIGS. 1 to 3.

### BRIEF DESCRIPTION OF THE DRAWINGS

FIG. 1 schematically shows a motor vehicle according to one aspect of the disclosure;

FIG. 2 schematically shows an architecture for data processing by a data processing device according to one aspect of the disclosure; and

FIG. 3 schematically shows a flow chart of a method according to an aspect of the disclosure.

### DETAILED DESCRIPTION OF THE DRAWINGS

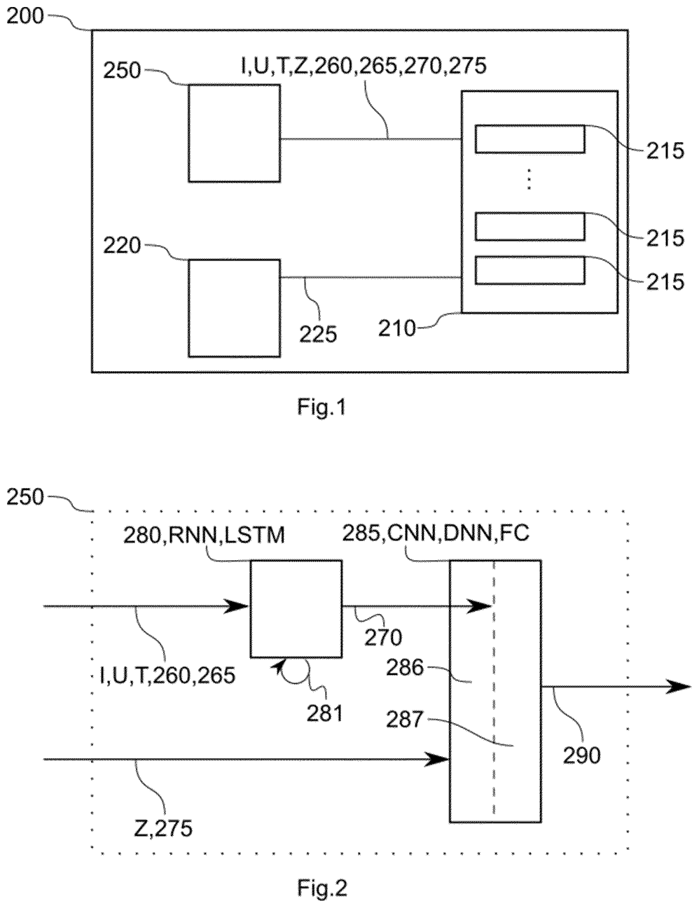

FIG. 1 schematically shows a motor vehicle 200 according to one aspect of the disclosure. The motor vehicle 200 is an electrically drivable motor vehicle 200. For this purpose, the motor vehicle 200 has an electric drive 220 and a battery 210. Electric energy 225 can be applied to the electric drive 220 by the battery 210, which the electric drive 220 can convert into mechanical energy. A state of charge of the battery 210 drops in this case. The electric drive 220 is configured for recuperation, thus to carry out regenerative braking, wherein mechanical energy is converted into electrical energy 225 which can be supplied to the battery 210. In this case and during charging of the battery 210 by an external charging station (not shown), the state of charge of the battery 210 can rise.

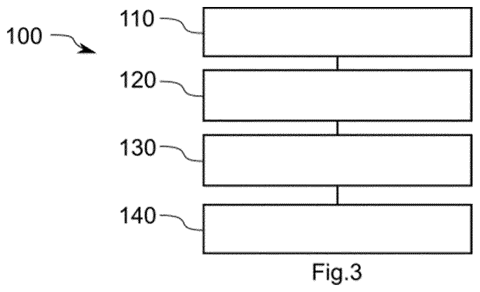

The motor vehicle 200 has a data processing device 250. The data processing device 250 is configured for monitoring battery cells 215 of the battery 210 of the motor vehicle 200. For this purpose, the data processing device 250 is configured to carry out the method 100 described with reference to FIG. 3 according to the architecture described with reference to FIG. 2.

The battery 210 has a plurality of battery cells 215, as schematically illustrated in FIG. 1. Each of the battery cells 215 can be characterized by a cell state variable 265. The cell state variables 265 comprise the cell current I, the cell temperature T, and the cell voltage U. The cell current I is typically a direct current (DC current), which is used for the electric drive 220 and becomes negative during charging and/or recuperating.

The cell current I, the cell voltage U, and the cell temperature T are measurable by measuring devices (not shown) connected to a control unit of the battery 210 and are transmittable to the data processing device 250. Further variables such as gradients, differences, and/or integrals can be ascertained or derived from the cell current I, the cell voltage U, and/or the cell temperature T. A time series 260 of the cell state variable 265 can be ascertained by a repeated measurement of the cell state variable 265 and transmitted to the data processing device 250 or ascertained in another embodiment by the data processing device 250 on the basis of a set of received cell state variables 265. The measurement of the cell current I, the cell voltage U, and the cell temperature T takes place, for example, during the journey and the time series 260 is provided with timestamps corresponding to the times of the measurements. The time series 260 can comprise cell state variables 265 which were measured every second and characterize a chronological development over thousands of seconds, for example.

A measurement of an impedance Z or an impedance spectrum 275 of the battery cells 215 is possible by way of a measuring device (not shown). For this purpose, an alternating current is applied to the battery cells 215 and a response signal is measured. The impedance spectrum 275 is transmitted to the data processing device 250 or ascertained in another embodiment by the data processing device 250 on the basis of received measured values of the impedance Z.

FIG. 2 schematically shows an architecture for data processing by a data processing device 250 according to an aspect of the disclosure.

The data processing device 250 comprises a memory (not shown) for storing data, a processor (not shown) for processing data, and interfaces to receive inputs of measured values and output information. The data processing device 250 is therefore configured to receive the cell state variables 265 described with reference to FIG. 1, thus the cell current I, the cell temperature T, and the cell voltage U or a time series 260 of the cell state variables 265 and the impedance Z and the impedance spectrum 275 as an input, as shown by the incoming arrows. The data processing device 250 is configured to ascertain state information 290 and output it, as shown by the outgoing arrow.

The data processing device 250 is furthermore configured to use a first neural network 280 and a second neural network 285 for processing the inputs and for determining the state information 290.

The first neural network 280 receives as inputs the cell state variables 265, thus the cell current I, the cell temperature T, and the cell voltage U or a time series 260 of the cell state variables 265, wherein the time series 260 has timestamps of the cell state variables 265. For example, the timestamps can be explicitly comprised in the time series 260 as variables and/or can result implicitly due to a periodicity of the measurement of the cell state variables 265.

The first neural network 280 comprises a recurrent neural network (RNN), for example, a long short-term memory network (LSTM). The neural network 280 comprises a time feedback 281, in order to be able to suitably take into consideration the history of the cell state variables 265 represented by the time series 260.

The first neural network 280 generates a state vector 270. The state vector 270 is a vector having information about the history of the measured battery cell 215. The state vector 270 can comprise one or more values, in other words an n-tuple with a natural number n. A corresponding state vector 270 can be calculated for each of the battery cells 215.

The second neural network 285 comprises a first layer 286 for the input of the impedance spectrum 275 and a second layer 287 downstream of the first layer 286 for the input of the state vector 270. The second neural network 285 therefore receives the information or the state vector 270 from the first neural network 280, and therefore information about a history of the battery cell 215 in a vector, plus the data of the impedance spectroscopy together, and creates a concatenated vector therefrom. The concatenated vector, thus the state vector 270 and the impedance spectrum 275, is then used to serve as an input for the second layer 287. If the measurement of the impedance spectrum 275 takes place, for example, at 75 frequencies, 2×75 measured values result, 75 measured values each for a real part of the impedance Z and for an imaginary part of the impedance Z. Therefore, 75 data points result which are to be input into the second layer 287. The first layer 286 for the input of the impedance spectrum 275 therefore comprises as many nodes as frequencies are used during the measurement of the impedance spectrum 275.

The first layer 286 is connected to the second layer 287. The second neural network 285 can have further layers (not shown). The second neural network 285 comprises a convolutional neural network (CNN) and/or a fully connected neural network (dense layer neural network (DNN)), in particular having fully connected layers (FC).

The output of the second neural network 285 is the state information 290 which is to be predicted, for example, the state of charge SOC and/or the state of health SOH. The second neural network 285 can cause valuable information from the impedance spectroscopy to be incorporated into the ascertainment of the state information 275 based on the output of the first neural network 280, which comprises measured variables, for example, during the journey before an impedance spectroscopy, plus the impedance spectrum 275 after the journey, for example, at constant direct current. Both neural networks 280, 285 are connected in two stages and form an artificial intelligence which enables an optimum cell state estimation.

The first neural network 280 can be trained by detecting test bench data. The state of charge of the battery cells 215 is measured in operation of the motor vehicle 200 and the time series 260 of the cell state variables 265 is recorded and labeled in accordance with the state of charge. The dependency of past values or the history and/or hysteresis is taken into consideration by the recording of the time series 260. The second neural network 285 can be trained by simulation of driving profiles and/or predetermined scenarios for the driving of the vehicle 200. For example, time series 260 of the cell state variables 265 are measured over hours and/or days and processed by the first neural network 280. At every opportunity, thus, for example, a standstill of the motor vehicle 200, a measurement of an impedance spectrum 275 and a comparison to the test bench data take place, wherein both networks 280, 285 can be trained according to the comparison via backward propagation.

FIG. 3 schematically shows a flow chart of a method 100 according to one aspect of the disclosure. The method 100 is a method 100 for monitoring battery cells 215 of a battery 210 of a motor vehicle 200. Such a motor vehicle 200 is described with reference to FIG. 1, wherein the underlying architecture for monitoring the battery cells 215 is described with reference to FIG. 2. The method 100 according to FIG. 3 will be described with reference to FIGS. 1 and 2.

According to FIG. 3, the method 100 comprises: detecting 110 a time series 260 of cell state variables 265 characterizing the battery cells 215.

A state vector 270 is ascertained 120 by input of the time series 260 into a first neural network 280.

An impedance spectrum 275 of the battery cells 215 is determined 130 by impedance spectroscopy. The determination 130 of the impedance spectrum 275 takes place when a chronological development of the cell voltage U and/or the cell current I meets a predetermined condition. The determination 130 of the impedance spectrum 275 takes place when the cell voltage U and/or the cell current I is constant. When the dynamic of the cell voltage U and/or the cell current I is less than a threshold value, the impedance measurement can take place. Otherwise, when the dynamic of the cell voltage U and/or the cell current I is greater than the threshold value, the impedance measurement does not take place and occurs at a later time at which the chronological development of the cell voltage U and/or the cell current I meets the predetermined condition. The determination 130 of the impedance spectrum 275 takes place when the cell current I falls below a predetermined cell current threshold and/or when the cell voltage meets a predetermined fluctuation condition.

State information 290 for monitoring the battery cells 215 is ascertained 140 by input of the impedance spectrum 275 and the state vector 270 into a second neural network 285.

A person skilled in the art recognizes that steps of the method 100 can be carried out simultaneously and/or continuously. The detection 110 of the time series 260 can be carried out essentially continuously and can also be carried out while, for example, the ascertainment 120 of the state vector 270 and/or the ascertainment of the state information 290 is carried out.

### LIST OF REFERENCE SIGNS

100 method
110 detection
120 ascertainment of a state vector
130 determination
140 ascertainment of state information
200 motor vehicle
210 battery
215 battery cell
220 electric drive
225 electric energy
250 data processing device
260 time series
265 cell state variables
270 state vector
275 impedance spectrum
280 first neural network
281 feedback
285 second neural network
286 first layer
287 second layer
290 state information
RNN recurrent neural network
LSTM long short-term memory network
CNN convolutional neural network
DNN dense layer neural network
FC fully connected layer
I cell current
T cell temperature
U cell voltage
Z cell impedance

1-11. (canceled)

12. A method for monitoring battery cells of a battery of a motor vehicle, the method comprising:
detecting a time series of cell state variables characterizing the battery cells;
ascertaining a state vector by input of the time series into a first neural network;
determining an impedance spectrum of the battery cells using impedance spectroscopy; and
ascertaining state information for monitoring the battery cells by input of the impedance spectrum and the state vector into a second neural network.

13. The method according to claim 12,
wherein the cell state variables comprise a cell current, a cell voltage, a cell temperature, and/or a variable derived therefrom.

14. The method according to claim 13,
wherein determining the impedance spectrum takes place when a chronological development of the cell current and/or the cell voltage meets a predetermined condition.

15. The method according to claim 14,
wherein determining the impedance spectrum takes place when the cell current is constant and/or falls below a predetermined cell current threshold.

16. The method according to claim 14,
wherein determining the impedance spectrum takes place when the cell voltage is constant and/or the chronological development of the cell voltage meets a predetermined variation condition.

17. The method according to claim 12,
wherein the first neural network comprises a recurrent neural network and/or a long short-term memory network.

18. The method according to claim 12,
wherein the second neural network comprises a convolutional neural network and/or a fully connected neural network.

19. The method according to claim 12,
wherein the second neural network has a first layer for input of the impedance spectrum and a second layer downstream of the first layer for input of the state vector.

20. A non-transitory computer readable medium having stored thereon commands, that which, upon execution by a computer, prompt the computer to carry out a method comprising:
detecting a time series of cell state variables characterizing a battery cells;
ascertaining a state vector by input of the time series into a first neural network;
determining an impedance spectrum of the battery cells using impedance spectroscopy; and
ascertaining state information for monitoring the battery cells by input of the impedance spectrum and the state vector into a second neural network.

21. The non-transitory computer readable medium according to claim 20,
wherein the cell state variables comprise a cell current, a cell voltage, a cell temperature, and/or a variable derived therefrom, and
wherein determining the impedance spectrum takes place when a chronological development of the cell current and/or the cell voltage meets a predetermined condition.

22. The non-transitory computer readable medium according to claim 21,
wherein determining the impedance spectrum takes place when the cell current is constant and/or falls below a predetermined cell current threshold.

23. The non-transitory computer readable medium according to claim 21,
wherein determining the impedance spectrum takes place when the cell voltage is constant and/or the chronological development of the cell voltage meets a predetermined variation condition.

24. The non-transitory computer readable medium according to claim 20,
wherein the first neural network comprises a recurrent neural network and/or a long short-term memory network; and/or
wherein the second neural network comprises a convolutional neural network and/or a fully connected neural network.

25. The non-transitory computer readable medium according to claim 20,
wherein the second neural network has a first layer for input of the impedance spectrum and a second layer downstream of the first layer for input of the state vector.

26. A data processing device for a motor vehicle, wherein the data processing device is configured to:
detect a time series of cell state variables characterizing the battery cells;
ascertain a state vector by input of the time series into a first neural network;
determine an impedance spectrum of the battery cells using impedance spectroscopy; and
ascertain state information for monitoring the battery cells by input of the impedance spectrum and the state vector into a second neural network.

27. The data processing device according to claim 26,
wherein the cell state variables comprise a cell current, a cell voltage, a cell temperature, and/or a variable derived therefrom, and
wherein determining the impedance spectrum takes place when a chronological development of the cell current and/or the cell voltage meets a predetermined condition.

28. The data processing device according to claim 27,
wherein determining the impedance spectrum takes place when the cell current is constant and/or falls below a predetermined cell current threshold.

29. The data processing device according to claim 27,
wherein determining the impedance spectrum takes place when the cell voltage is constant and/or the chronological development of the cell voltage meets a predetermined variation condition.

30. The data processing device according to claim 26,
wherein the first neural network comprises a recurrent neural network and/or a long short-term memory network; and/or
wherein the second neural network comprises a convolutional neural network and/or a fully connected neural network.

31. The data processing device according to claim 26,
wherein the second neural network has a first layer for input of the impedance spectrum and a second layer downstream of the first layer for input of the state vector.
